(19) United States
(12) Patent Application Publication
(10) Pub. No.: US 2013/0095603 A1
(43) Pub. Date: Apr. 18, 2013

(54) METHOD FOR THE TREATMENT OF A METAL CONTACT FORMED ON A SUBSTRATE

(71) Applicant: Raphaël Cabal, Perigueux (FR)

(72) Inventor: Raphaël Cabal, Perigueux (FR)

(73) Assignee: Commissariat a L'Energie Atomique et aux Energies Alternatives, Paris (FR)

(21) Appl. No.: 13/634,498

(22) PCT Filed: Mar. 11, 2011
(86) PCT No.: PCT/IB11/51042

§ 371 Date: Dec. 3, 2012

(30) Foreign Application Priority Data
Mar. 12, 2010 (FR) 1001007

(51) Int. Cl. H01L 31/18

(52) U.S. Cl. CPC H01L 31/18
USPC 438/98

(57) ABSTRACT

The invention relates to a method for obtaining a metal contact on a substrate, comprising the following steps: (a) depositing a metal pattern in the form of a paste formed from a mixture of a metal power and a solvent, (b) heating the assembly formed in step (a) in order to evaporate the solvent, and (c) annealing same in order to form a metal contact between the metal pattern and the substrate. The invention is characterised in that it also includes a step (d) in which the metal contact is heated by laser at an energy density of between 0.5 J/cm² and 15 J/cm².

The present invention relates to a process for treating a metal contact produced on a substrate, a dielectric layer possibly being provided between the substrate and the metal.

The process according to the invention may especially be applied during manufacture of a photovoltaic cell.

Specifically, in this sort of application, metal contacts are deposited on the front and back side of the substrate in order to allow electrons generated via the photoelectric effect in the substrate to be collected.

One production process commonly used in the photovoltaic industry comprises the following steps.

A substrate, for example made of p-type silicon, is first cut to the desired size.

In order to improve the quality of the surfaces cut out in this way, chemical etching, for example with alkalis, is then carried out.

Generally, a step of texturing the front side is carried out in order to form an optical structure with the aim of trapping the photons of incident light in the substrate so as to increase the efficiency of the cell. This may for example be pyramid-shaped optical structures produced by chemical etching with sodium hydroxide.

The surfaces of the substrate are then doped n-type, for example by diffusion of phosphorus. A prior step may consist in carrying out an etch with an acid so as to neutralize any residual alkalis and remove any impurities since the surfaces of the substrate must be clean before the doping is carried out.

Next, the n-type doping of the vertical edges is removed in order to isolate these edges. This is for example achieved by plasma etching.

A dielectric layer is then deposited over all of the front side of the substrate, so as to provide an antireflection function. This dielectric layer may be produced by vapor deposition of silicon nitride (SiN).

A metal contact is then produced on the front and back sides of the substrate.

In particular, on the back side, a paste is deposited comprising an aluminum powder mixed with a solvent. This deposition is generally obtained by screen printing. The paste is deposited in a chosen pattern, in the form of a mesh or a uniform layer.

Next, the paste is heated in order to remove the solvent and leave behind only the aluminum. The heating is generally carried out in an oven at a temperature between 100° C. and 200°°C., so as to remove solvents and organic compounds.

This technique for depositing the metal pattern is very advantageous in terms of cost and alignment of said pattern relative to the substrate.

Finally a high-temperature step of annealing the substrate thus equipped with the dielectric layer and the front and back side metal patterns is carried out.

An “anneal” is conventionally defined in metallurgy as being a heat treatment the temperature profile of which comprises at least one period at a temperature above the melting point of the material in question.

This step allows a durable metal contact to be formed between said patterns and the substrate while removing the last of the nonmetal residues.

This step is a delicate step because it is necessary to control the thermal profile of the heating operation depending on the nature and composition of the metal paste. In particular there is a risk, if the anneal is too long and/or carried out at too high a temperature, that the photovoltaic cell will be degraded, the contacts possibly passing through the active zone of the cell.

Although a high-quality metal contact can be achieved between the metal patterns and the substrate with the process described above, the electrical conductivity of the metal contacts nevertheless remains limited. This is especially a result of the process used to deposit the metal, which process is based on deposition of a metal paste formed by mixing a powder of the metal in question with a solvent.

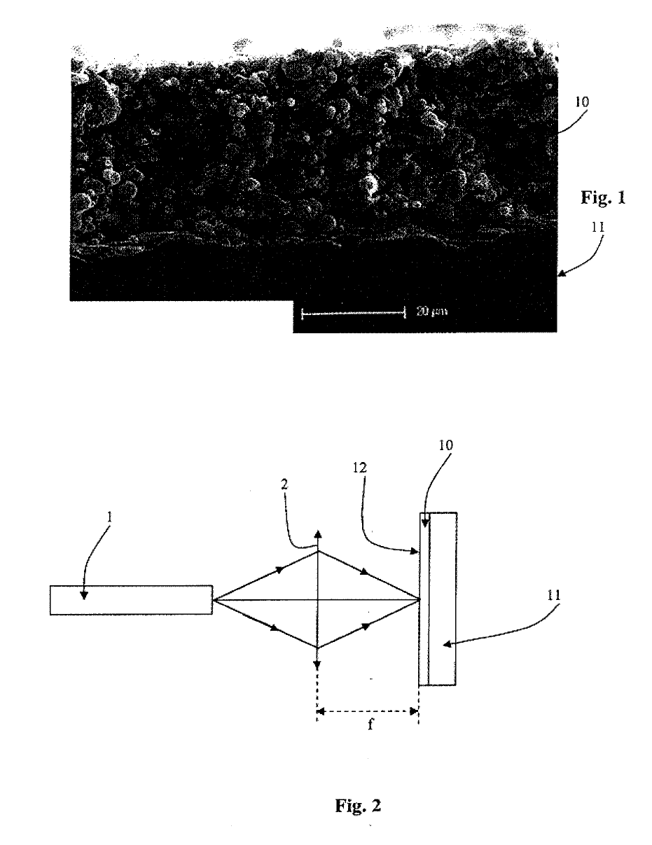

Specifically, when the paste has dried, the metal pattern has a structure consisting of an agglomerate of particles, which does not make it easy to obtain a low electrical resistance in the metal contact. A metal pattern 10 made of aluminum deposited on a substrate 11 made of silicon is shown by way of example in FIG. 1 in a cross section imaged with a scanning electron microscope.

In addition, this particle agglomerate is particularly prone to oxidation because this structure consisting of an agglomerate of particles has a large surface area.

This is particularly disadvantageous in the context of application to manufacturing photovoltaic cells. Similar problems may however arise in other applications, provided that a metal contact is to be formed on a substrate using a step of depositing a paste formed by mixing a metal powder with a solvent.

Thus one object of the invention is to increase the electrical conductivity of a metal contact produced on a substrate, a dielectric layer possibly being provided between the substrate and the metal pattern.

Another object of the invention is to improve the ability of a metal contact to withstand oxidation effects, the metal part of which contact is obtained with a paste formed by mixing a metal powder with a solvent.

To achieve at least one of these objects, the invention provides a process for obtaining a metal contact on a substrate, comprising the following steps:

(a) depositing a metal pattern in the form of a paste formed from mixing a metal powder with a solvent;

(b) heating the assembly thus formed in step (a) so as to evaporate the solvent; and

(c) carrying out an anneal in order to form an metal contact between the metal pattern and the substrate, characterized in that it furthermore comprises a step (d) in which the metal contact is heated using a laser with an energy density between 0.5 J/cm² and 15 J/cm².

The process according to the invention will possibly have other technical features according to the invention, whether alone or in combination, namely:
step (a) is a step of screen printing;
the metal pattern is at least 1 μm in thickness;
the metal contact takes the form of a mesh;
the metal contact takes the form of a layer;
the metal contact comprises silver, aluminum, or a silver-aluminum alloy;
the process comprises a step of depositing a dielectric layer on the substrate before step (a);
the laser emits in the infrared range, for example at a wavelength of 1064 nm;
the laser being a laser-diode-pumped laser, the peak current drawn by the laser diode is between 20 A and 30 A, preferably between 25 A and 28 A;
the laser emits pulses at a frequency of between 30 kHz and 60 kHz, preferably between 40 kHz and 60 kHz;
the degree of coverage of the area of the metal contact between two pulses is at least 95% and preferably at least 97%;
the scan rate of the laser is lower than 10 m/s, for example between 1 m/s and 10 m/s;
the laser emits pulses the length of which is between 1 ns and 1 μs, for example between 100 ns and 1 μs; and
the laser being a pulsed laser-diode-pumped laser emitting in the infrared range, said laser is employed under the following conditions:
   the frequency of the pulses lies between 40 kHz and 60 kHz;
   the degree of coverage of the area of the metal contact between two pulses is 97% or more;
   the scan rate of the laser over the area of the metal contact is between 1 m/s and 10 m/s and preferably between 1 m/s and 5 m/s; and
   the laser diode draws a peak current of between 25 A and 28 A.

Other features, objects and advantages of the invention will be revealed by the detailed description, given below with reference to the following figures:

FIG. 1, showing a cross-sectional view of a metal pattern obtained in a known way by deposition of a metal paste formed by mixing a metal powder with a solvent;

FIG. 2, showing a device for implementing the process according to the invention;

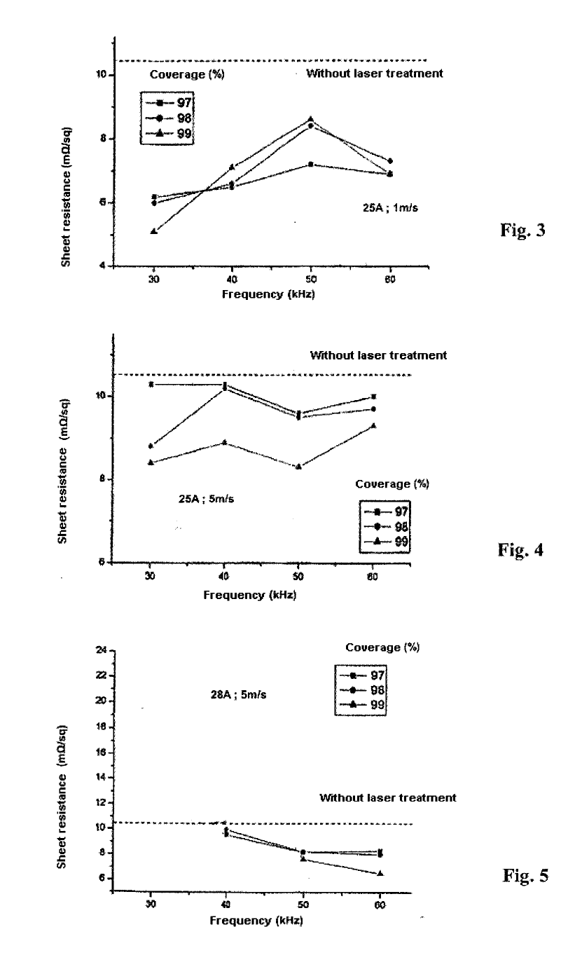

FIG. 3, showing, for a laser scanning over the area of the metal contact at a rate of 1 m/s, the variation in the sheet resistance of the metal contact as a function of the repetition frequency of the light pulses emitted by the laser, for various degrees of coverage of the area of the metal contact irradiated by two pulses;

FIG. 4, showing, for a laser scanning over the area of the metal contact at a rate of 3 m/s, the variation in the sheet resistance of the metal contact as a function of the repetition frequency of the light pulses emitted by the laser, for various degrees of coverage of the area of the metal contact irradiated by two pulses;

FIG. 5, showing, for a laser scanning over the area of the metal contact at a rate of 5 m/s, the variation in the sheet resistance of the metal contact as a function of the frequency of the light pulses emitted by the laser, for various degrees of coverage of the area of the metal contact irradiated by two pulses;

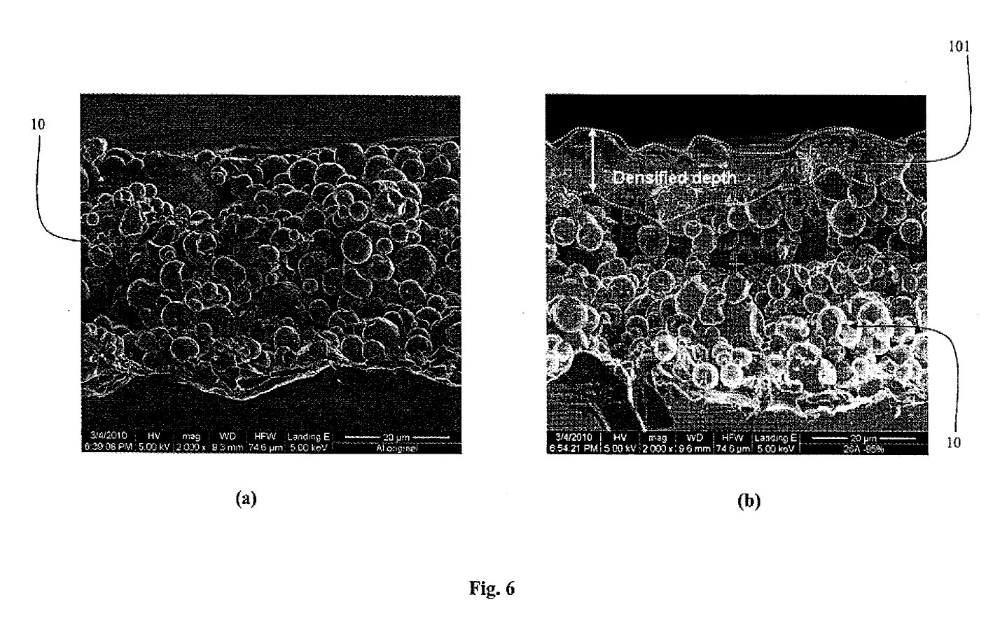

FIG. 6, comprising FIGS. 6(a) and 6(b), FIG. 6(a) being a cross-section view of an aluminum metal pattern obtained in a known way by depositing an aluminum paste formed by mixing an aluminum powder with a solvent, and FIG. 6(b) being the metal pattern in FIG. 6(a) after treatment by the process according to the invention; and

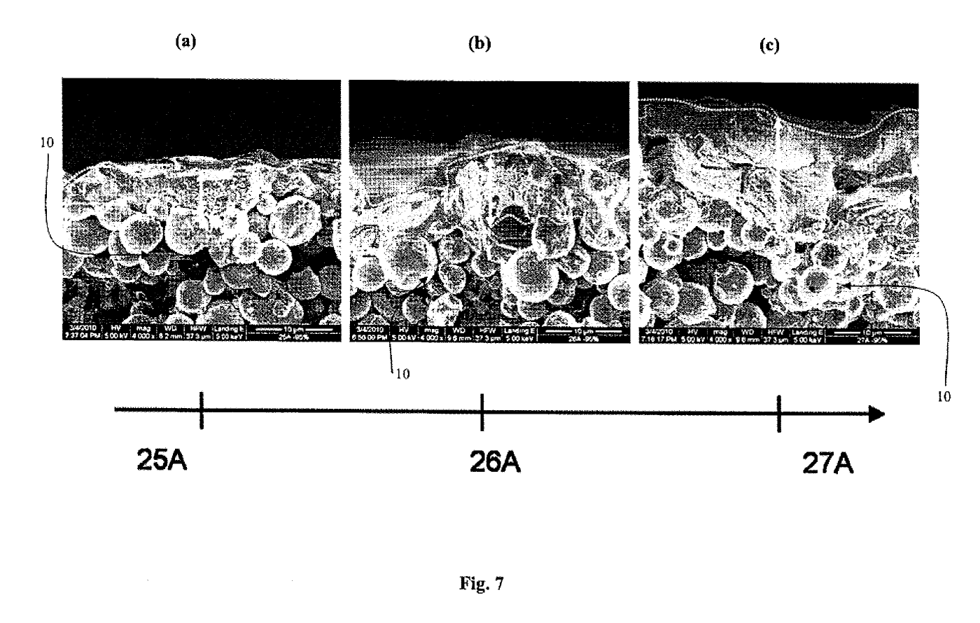

FIG. 7, comprising FIGS. 7(a) to 7(c), which all show a cross-sectional view of an aluminum metal pattern obtained by the process according to the invention, with different diode currents.

The invention relates to a process for treating a metal contact produced on a substrate, in which the contact has been obtained using the following steps (a), (b) and (c):

(a) depositing a metal pattern in the form of a paste formed from mixing a metal powder with a solvent;

(b) heating the assembly thus formed in step (a) so as to evaporate the solvent; and

(c) carrying out an anneal in order to form an metal contact between the metal pattern and the substrate.

Step (a) may be a step of screen printing.

The metal pattern deposited in step (a) may be at least 1 pm in thickness. The metal pattern obtained after steps (a) to (c) is an agglomerate of particles, as shown in FIG. 1. This metal pattern may also be qualified as porous since there are spaces between the metal particles.

The metal pattern may take the form of a mesh or the form of a layer. The metal pattern may especially comprise silver, aluminum, or a silver-aluminum alloy.

The nature of the metal used in the paste is chosen depending on the type of metal contact desired. Thus, for a photovoltaic cell, a backside silver-aluminum alloy metal contact may be envisioned.

A dielectric layer may be provided between the metal pattern and the substrate. The process furthermore comprises a step (d) in which the metal contact is heated by a laser with an energy density between 0.5 J/cm² and 15 J/cm².

The electrical resistance of this contact is thus decreased, without damaging the metal contact or the substrate and without debonding the contact from the substrate.

As will be described in the rest of the description, a number of parameters may influence the value of the energy density obtained at the surface of the metal contact.

FIG. 2 shows a schematic of a device for implementing step (d) of the process.

The laser 1, used in this device to heat the metal contact, may emit in the infrared range, for example at a wavelength of 1064 nm. This laser 1 may be a diode-pumped laser, such as a Nd:YAG laser emitting at 1064 nm and pumped at 808 nm by a laser diode.

The laser 1 described above is a laser that emits in the infrared range. Specifically, this wavelength range is the most critical for metal contacts produced on silicon substrates since silicon absorbs infrared radiation and risks being damaged by this radiation (strain induced by increasing volume).

As a variant, the laser used could be a laser that emits in the ultraviolet range or in the visible range (for example in the “green” at a wavelength of about 438 nm).

When the laser 1 is a laser-diode-pumped laser, the peak current drawn by the laser diode may be between 20 A and 30 A and preferably between 25 A and 28 A.

Above 30 A, the contact and the substrate run the risk of being damaged. Generally, in this case, partial ablation and then debonding of the contact is observed, with the contact being torn from the underlying substrate.

In this range of peak diode-current values, an energy density of between 0.5 and 15 J/cm² may be obtained at the surface of the metal contact.

The electrical resistance of the metal contact is therefore substantially diminished, without damage. In addition, a metal contact that is durably fixed to the substrate is obtained, i.e. there is no risk of the contact and the substrate debonding (blistering effect).

The laser 1 may moreover be a pulsed laser.

In this case, the laser 1 may emit pulses at a repetition frequency of between 30 kHz and 60 kHz, and preferably between 40 kHz and 60 kHz.

This range of values for the repetition frequency promotes the decrease in the electrical resistance of the metal contact without adversely affecting the metal contact, the substrate or the connection between the two.

Moreover, the degree of coverage of the area of the metal contact between two pulses is at least 95% and preferably at least 97%. One of the following degrees of coverage may especially be envisioned: 97%, 98% or 99%.

The expression “degree of coverage” is understood to mean the percentage of the area of the contact that is subjected to two passes of the laser in succession in the scan direction. It will therefore be understood that these two passes are slightly shifted, perpendicular to the scan direction of the laser.

A high degree of coverage has the advantage of making it easier to obtain a minimum energy density and decreases the electrical resistance of the metal contact.

The scan rate of the laser may be lower than 10 m/s and preferably between 1 m/s and 10 m/s.

This rate range makes it possible to obtain a productivity that is acceptable from the industrial standpoint while preserving the metal contact and the substrate.

The pulse length of each pulse may moreover be between 1 ns and 1 μs.

The device shown in FIG. 2 also comprises a lens 2 with a focal distance f. The back side 12 of the back contact 10 is placed at a distance f from the lens, so that the lens 2 focuses the laser beam on this back side 12.

Other possible designs may be conceived of with regard to FIGS. 3 to 5.

FIGS. 3 to 5 all show the sheet resistance of the metal contact on the Y-axis and the repetition frequency of the pulses on the X-axis. As is known to those skilled in the art, it will be recalled that the sheet resistance R_{c} of this contact is related to its electrical resistivity [symbol] and to its thickness e by the relationship: R_{c}= [symbol] /e, expressed below in mΩ/carré.

In addition, the data presented in FIGS. 3 to 5 were obtained from measurements carried out using what is called the “four-point” (or Van der Pauw) method known to those skilled in the art, the metal contact forming a thin film. Of course, the thickness e of the metal contact was the same for all the tests carried out, whether with or without laser treatment.

In FIG. 3, the scan rate of the laser over the surface of the metal contact was set to 1 m/s and the peak current of the diode to 25 A. In this figure, three curves have been drawn showing the variation in the sheet resistance obtained for the metal contact after laser treatment as a function of the frequency of the pulses, for various degrees of coverage by two pulses, namely 97%, 98% and 99%.

A reference is shown by the dashed line in FIG. 3.

This reference was measured after a metal contact had been produced using the prior-art process, the metal of said contact being aluminum in contact with a silicon substrate, a dielectric layer being provided between the two.

The reference metal contact was therefore not subjected to a laser treatment.

In other words, the reference metal contact was especially subjected to steps (a) to (c) but not to step (d), in contrast to the other tests carried out.

In this particular instance the reference sheet resistance was measured to be 10.5 mΩ/carré.

For all the tests carried out, the electrical resistance of the contact decreased relative to the reference for the entire range of pulse frequencies tested, namely from 30 kHz to 60 kHz, and moreover whether the value of the degree of coverage was 97%, 98% or 99%.

More precisely, the values of the electrical resistance obtained were between 5.1 and 8.7 mΩ/carré, i.e. a decrease of between −51.4% and −17.1% relative to the reference value. In particular, the lowest resistance was obtained at a frequency of 30 kHz and for a degree of coverage of 99%.

In FIG. 4, the scan rate of the laser over the surface of the metal contact was increased to 5 m/s while the peak current was kept at 25 A. Three curves have been drawn showing the variation in the electrical resistance (sheet resistance) of the metal contact after laser treatment as a function of the frequency of the pulses, for various degrees of coverage by two pulses, namely 97%, 98% and 99%.

The reference (metal contact not subjected to laser treatment) is still shown by a dashed line in FIG. 4, its value being 10.5 mΩ/carré.

For all of the tests carried out, the electrical resistance of the contact decreased relative to the reference for the entire range of tested pulse frequencies, namely 30 kHz to 60 kHz, and moreover whether the value of the degree of coverage was 97%, 98% or 99%.

More precisely, the values obtained for the electrical resistance were between 8.1 and 10.3 mΩcarré, i.e. a decrease of between about −22.9% and −2% relative to the reference value.

Generally, the resistance obtained for the metal contact with the tests shown in FIG. 4 was higher than that obtained with the tests shown in FIG. 3.

This is related to the fact that the increase in the scan rate decreases the energy density impacting the metal contact.

For this scan rate of 5 m/s, a degree of coverage of 99% will preferably be chosen, which allowed the lowest resistances to be obtained in the entire range of frequencies tested.

In FIG. 5, the scan rate of the laser over the surface of the metal contact was kept at 5 m/s and the peak current increased to 28 A. Three curves have been drawn showing the variation of the electrical resistance (sheet resistance) of the metal contact after laser treatment, as a function of the repetition frequency of the pulses, between 40 kHz and 60 kHz, for various degrees of coverage by two pulses.

The reference (metal contact not subjected to laser treatment) is still shown by a dashed line in FIG. 5, its value being 10.5 mΩ/carré.

With a higher diode current value, relative to the tests shown in FIG. 4, it was preferable to increase the repetition frequency of the pulses in order to decrease the contact resistance with respect to the reference (dashed line).

By way of summary, if the laser is a pulsed laser-diode-pumped laser emitting in the infrared range, a person skilled in the art will be able to use the following conditions to obtain an energy density of between 0.5 J/cm² and 15 J/cm²:
the frequency of the pulses lies between 40 kHz and 60 kHz;
the degree of coverage of the area of the metal contact between two successive pulses is 97% or more;
the scan rate of the laser over the area of the metal contact is between 1 m/s and 10 m/s and preferably between 1 m/s and 5 m/s; and
the laser diode draws a peak current of between 25 A and 28 A.

For the data shown in FIGS. 3 to 5, the apparatus used was set to the “100 ns-1 μs” pulse-length position.

After the tests shown in FIGS. 3 to 5 had been carried out, the Applicant was able to observe that the structure, said to consist of an agglomerate of particles, obtained with the conventional process, had been modified by the laser step according to the invention.

Thus, the laser treatment had the effect of changing the particle-agglomerate structure into a structure that was observed to be more continuous than the particle-agglomerate structure.

This may be seen in appended FIGS. 6 and 7.

FIG. 6, which comprises FIGS. 6(a) and 6(b), provides a first illustration of the benefit of the invention.

FIG. 6(a) shows a cross-sectional view of a metal pattern 10 made of aluminum, obtained after implementing steps (a) to (c) of the process. This metal pattern was formed by a porous agglomerate of particles. In other words, there were free spaces between the metal particles, these spaces promoting oxidation of the surface of the metal particles.

FIG. 6(b) shows the same cross-sectional view of this same pattern 10 after the laser treatment step (d) according to the invention had been carried out. In this particular instance, step (d) was carried out with a degree of coverage of 95% and a diode current of 26 A.

The metal pattern 10 thus obtained had a densified surface layer 101, qualified as being continuous since there were no longer any spaces allowing gas to penetrate into the core of the metal pattern. This surface layer was therefore not formed by an agglomerate of particles. Moreover, it will be observed that the size of the particles just below this continuous surface layer is generally larger than that of those in FIG. 6(a).

This is to be related to the results shown in FIGS. 3 to 5.

Specifically, it will be understood that there is a link between the increase in the electrical conductivity of the metal contact and the existence of this densified surface layer, which may be qualified as continuous, on the metal pattern. In addition, this continuous surface layer forms a barrier to external air, thereby limiting oxidation effects over time and, therefore, allowing a good electrical conductivity to be preserved in use.

FIG. 7, which comprises FIGS. 7(a) to 7(c), provides another illustration of the benefit of the invention.

These figures all show cross-sectional views of a metal pattern 10 obtained by implementing steps (a) to (d) of the process under the same conditions, only the diode current differing. The degree of coverage was in particular kept at 95%.

Specifically, for FIG. 7(a), the diode current used was 25 A. It was 26 A and 27 A for FIGS. 7(b) and 7(c), respectively.

It will be observed that the thickness of the surface layer, which may be qualified as continuous, increases with the increase in the diode current. It will thus be understood that the more the diode current is increased, the higher the energy density of the laser beam becomes, and the more the thickness of the densified zone increases.

The treatment of the metal contact described above will advantageously be applied to the manufacture of photovoltaic cells.

The laser described above is a pulsed laser emitting in the infrared range. As a variant, it could however be envisioned to use a laser emitting light continuously, in the infrared, visible or ultraviolet range irrespectively.

1. A method for obtaining a metal contact on a substrate, comprising the steps of:
(a) depositing a metal pattern in the form of a paste comprising a metal powder and a solvent onto the substrate to form an assembly;
(b) heating the assembly formed in step (a) to evaporate the solvent; and
(c) carrying out an annealing step to form a metal contact between the metal pattern and the substrate, and
(d) heating the metal contact using a laser with an energy density between 0.5 J/cm² and 15 J/cm².

2. The method of claim 1, wherein step (a) comprises a step of screen printing.

3. The method of claim 1, wherein the metal pattern is at least 1 μm in thickness.

4. The method of claim 1, wherein the metal contact takes the form of a mesh.

5. The method of claim 1, wherein the metal contact takes the form of a layer.

6. The method of claim 1, wherein the metal contact comprises silver, aluminum, or a silver-aluminum alloy.

7. The method of claim 1, further comprising a step of depositing a dielectric layer on the substrate before step (a).

8. The method of claim 1, wherein the laser emits in the infrared range.

9. The method of claim 1, wherein the laser is a laser-diode-pumped laser, with a peak current drawn by the laser diode is between 20 A and 30 A.

10. The method of claim 1, wherein the laser emits pulses at a frequency between 30 kHz and 60 kHz.

11. The method of claim 1, wherein the metal contacts comprise a degree of coverage of an area between two pulses of at least 95%.

12. The method of claim 1, wherein the laser comprises a scan rate lower than 10 m/s.

13. The method of claim 1, wherein the laser emits pulses between 1 ns and 1 μs in duration.

14. The method of claim 1, wherein the laser is a pulsed laser-diode-pumped laser emitting in the infrared range, and said laser is employed under the following conditions:
the frequency of the pulses lies between 40 kHz and 60 kHz;
the degree of coverage of the area of the metal contact between two pulses is 97% or more;
the scan rate of the laser over the area of the metal contact is between 1 m/s and 10 m/s and preferably between 1 m/s and 5 m/s; and
the laser diode draws a peak current of between 25 A and 28 A.

15. The method of claim 8, wherein the infrared range wavelength is about 1064 nm.

16. The method of claim 9, wherein the peak current drawn by the laser diode is between 25 A and 28 A.

17. The method of claim 10, wherein the laser emits pulses at a frequency between 40 kHz and 60 kHz.

18. The method of claim 11, wherein the degree of coverage is at least 97%.

19. The method of claim 12, wherein the scan rate is between 1 m/s and 10 m/s.

20. The method of claim 13, wherein the laser emits pulses between 100 ns and 1 μs.

21. The method of claim 14, wherein the scan rate is between 1 m/s and 5 m/s.
